(19) United States
(12) Patent Application Publication
(10) Pub. No.: US 2013/0240944 A1
(43) Pub. Date: Sep. 19, 2013

(54) MOUNTING DEVICE FOR A LIGHT EMITTING DIODE

(71) Applicants: Wen-Fu Wang, Taipei City (TW); Chung-Yu Chen, New Taipei City (TW); I-Lung Yang, New Taipei City (TW)

(72) Inventors: Wen-Fu Wang, Taipei City (TW); Chung-Yu Chen, New Taipei City (TW); I-Lung Yang, New Taipei City (TW)

(73) Assignee: KEEPER TECHNOLOGY CO., LTD., New Taipei City (TW)

(21) Appl. No.: 13/418,670

(22) Filed: Mar. 13, 2012

(51) Int. Cl. H01L 33/62

(52) U.S. Cl. 257/99; 257/E33.066

(57) ABSTRACT

A mounting device for a light emitting diode (LED) includes an LED and a conductor connecting to the LED. The LED includes two electrode leads bending outward and each electrode lead has a distal end. A protrusion is formed from the bottom surface of the distal end. The conductor has two electrode boards. A mounting leadframe is formed and protrudes from the surface of each electrode board and corresponds to one of the electrode leads, and a mounting hole is formed in each electrode board at a position corresponding to one of the protrusions. In addition, the distal end of each electrode lead is inserted respectively into the corresponding mounting leadframe, and each protrusion engages the corresponding mounting hole. With the insertion of the LED into the conductor and the engagements between protrusions and mounting holes, the LED is securely and stably mounted on the conductor.

### BACKGROUND OF THE INVENTION

1. Field of the Invention

The present invention relates to a mounting device for a light emitting diode, and more particularly to a mounting device for securely mounting a light emitting diode on a conductor.

2. Description of the Prior Arts

Light emitting diodes (LEDs) have low temperature and low power consumption properties and thus are widely used for electronic products such as lighting or the indicator lights. A Light emitting diode has a die encapsulated inside a transparent silicone rubber and electrode pins extending downwardly. The conventional LEDs are connected to two circuit boards with spot-welded structures.

With reference to FIG. 11, to connect the conventional LED 30 onto two circuit boards 32, the two electrode pins 31 of the LED 30 are bent into 90 degrees, and then the distal ends of the two electrode pins 31 are respectively soldered on the positive and negative electrodes on the circuit boards 32 by spot welding process. Accordingly, the LED 30 is electrically connected to a power supply device via the circuit boards 32.

However, the solder 33 needs a period of time for solidifying. If the LED 30 is not stably positioned by the welding spot within this period, the position of the LED 30 is easily shifted. In order to avoid the shifting of the LED 30, the LEDs 30 have to be connected to the circuit boards 32 one by one and until the solders 33 of a previous LED 30 have been solidified. However, this is time-consuming and is hard to ensure that, during the welding time, the shifting of the LED 30 will not occur.

To overcome the shortcomings, the present invention provides a mounting device to mitigate or obviate the aforementioned problems.

### SUMMARY OF THE INVENTION

Given that the aforesaid drawbacks of the prior art such as spot-welded structures will cause the shifting of the LED, the present invention mainly provides a mounting device for securely mounting an LED on a conductor.

The mounting device in accordance with the present invention comprises: an LED and a conductor connecting to the LED.

The LED comprises two electrode leads, wherein the two electrode leads are bent outward relative to each other and each electrode lead has a distal end. A protrusion is formed from the bottom surface of the distal end.

The conductor comprises two electrode boards. A mounting leadframe is formed and protrudes from the surface of each electrode board and corresponds to one of the electrode leads of the LED. A mounting hole is formed in each electrode board at a position corresponding to one of the protrusions. The distal end of each electrode lead is inserted respectively into one of the mounting leadframes and each protrusion is engaged in the corresponding mounting hole, and then the distal end is mounted on the conductor with the corresponding mounting leadframe.

According to the aforementioned structure, the present invention is to insert each electrode lead of the LED into the corresponding mounting leadframe respectively and in the meanwhile to engage each protrusion of the electrode leads with the corresponding mounting hole on the conductor, and to mount each electrode lead on the conductor by the corresponding mounting leadframe. Thus the LED is stably mounted on the conductor. With the two mounting holes in the conductor that are previously formed in the conductor, the LED can be precisely located on the conductor. Moreover, after connecting the LED to the mounting leadframes on the conductor, a punching process is applied to the mounting leadframes along a direction from the mounting leadframes toward the electrode leads to clamp the LED more tightly to the conductor, thus avoiding the shifting of the LED. Consequently, this method is more timesaving and convenient compared to the method of welding.

Other objectives, advantages and novel features of the invention will become more apparent from the following detailed description when taken in conjunction with the accompanying drawings.

### BRIEF DESCRIPTION OF THE DRAWINGS

FIG. 1 is a perspective view of a mounting device for a light emitting diode in accordance with the present invention;

FIG. 2 is an exploded perspective view of the mounting device in FIG. 1;

FIG. 3 is a side view in partial section of the mounting device in FIG. 1;

FIG. 4 is another side view in partial section of the mounting device in FIG. 1;

FIG. 5 is a top view of the mounting device in FIG. 1;

FIG. 6 is a bottom view of the mounting device in FIG. 1;

FIG. 7 is a perspective view of a second embodiment of a mounting device for a light emitting diode in accordance with the present invention;

FIG. 8 is an exploded perspective view of the mounting device in FIG. 7;

FIG. 9 is a side view in partial section of the mounting device in FIG. 7;

FIG. 10 is another side view of the mounting device in FIG. 7; and

FIG. 11 is a perspective view of a spot-welded structure of a conventional light emitting diode in accordance with the prior art.

### DETAILED DESCRIPTION OF THE PREFERRED EMBODIMENTS

The present invention provides a mounting device for securely and stably mounting a light emitting diode on a conductor.

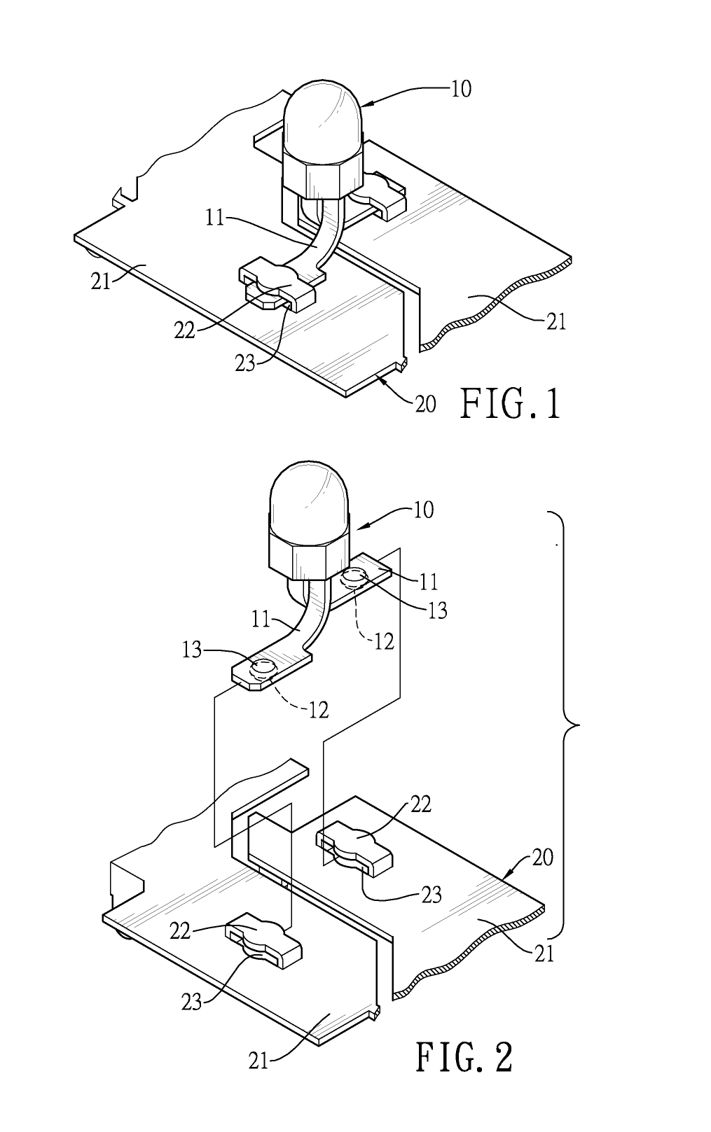

With reference to FIGS. 1 and 2, a first embodiment of a mounting device for a light emitting diode in accordance with the present invention comprises a light emitting diode 10 and a conductor 20.

The light emitting diode 10 comprises two electrode leads 11 serving respectively as positive and negative electrodes, wherein the two electrode leads 11 are bent outward relative to each other, and each electrode lead 11 has a distal end. A protrusion 12 is formed downward from the bottom surface of the distal end. In the present embodiment, the distal end of each electrode lead 11 is plate-shaped, and the protrusions 12 are hemispherical. Each protrusion 12 is formed with a punching process along a direction from a top surface to the bottom surface of the distal end. Thus, a hemispherically shaped recess 13 is formed in the top surface of the distal end of each electrode lead 11 at a position corresponding to the protrusion 12.

The conductor 20 comprises two electrode boards 21 serving respectively as positive and negative electrodes. A mounting hole 23 is formed in each electrode board at a position corresponding to one of the protrusions 12 of the light emitting diode 10. Furthermore, a mounting leadframe 22 protrudes from the surface of each electrode board 21, is formed over the mounting hole 23 in the electrode board 21 and corresponds to one of the electrode leads 11. The two electrode leads 11 of the light emitting diode 10 are respectively inserted into the mounting leadframes 22 of the two electrode boards 21 and the two protrusions 12 on the electrode leads 11 are respectively engaged in the mounting holes 23 on the electrode boards 21. In the present embodiment, the lengths of the mounting leadframes 22 match the widths of the plate-shaped distal ends of the electrode leads 11 of the light emitting diode 10. Additionally, the mounting holes 23 are round holes so as to fit and engage the hemispherically shaped protrusions 12. Furthermore, the mounting holes 23 and the mounting leadframes 22 are formed together by a punching process along a direction from the bottom face to the top face of the conductor 20, thus each mounting hole 23 aligns with the corresponding mounting leadframe 22.

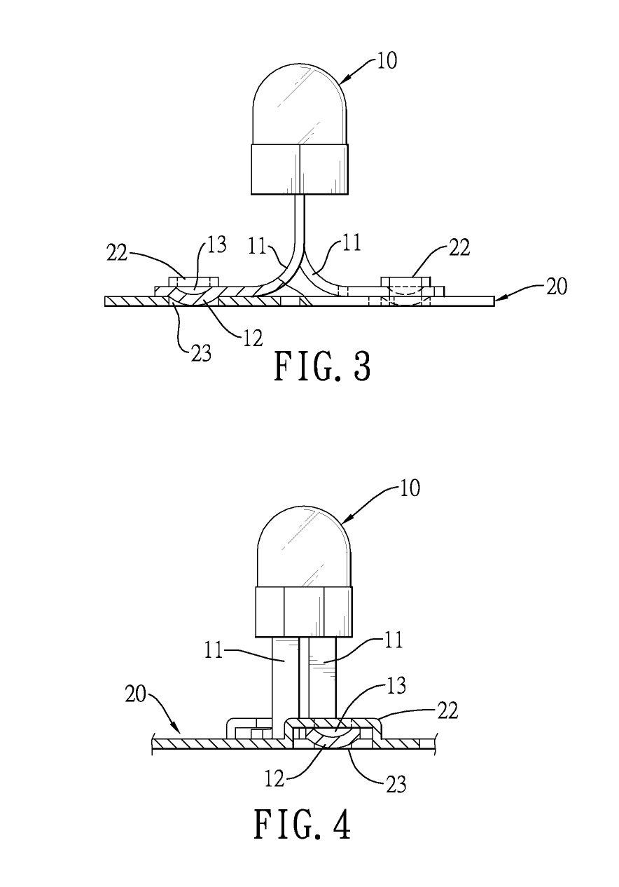

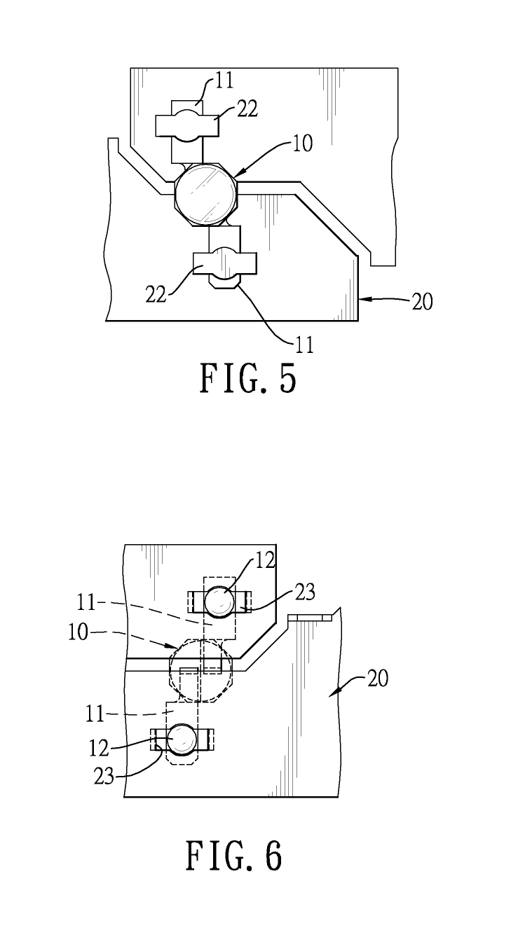

With reference to FIGS. 3 and 4, the distal end of each electrode lead 11 of the light emitting diode 10 is inserted respectively into one of the mounting leadframes 22 of the conductor 20. With the plate shape of the distal ends of the electrode leads 11, the contact area between the electrode leads 11 and the mounting leadframes 22 is increased. Consequently, the light emitting diode 10 has an excellent electrical connection with the conductor 20. With reference to FIGS. 5 and 6, each protrusion 12 on the electrode lead 11 respectively engages the mounting holes 23 on the electrode boards 21. Because the shape of the mounting holes 23 fits the shape of the protrusions 12, the protrusions 12 are capable of securely engaging the mounting holes 23 and holding the electrode leads 11 securely to the mounting leadframes 22 so as to securely mount the light emitting diode 10 on the conductor 20. Moreover, after connecting the light emitting diode 10 to the mounting leadframes 22 on the conductor 20, a punching process is applied to the mounting leadframes 22 along a direction from the mounting leadframes 22 toward the electrode leads 11 to clamp the light emitting diode 10 more tightly to the conductor 20.

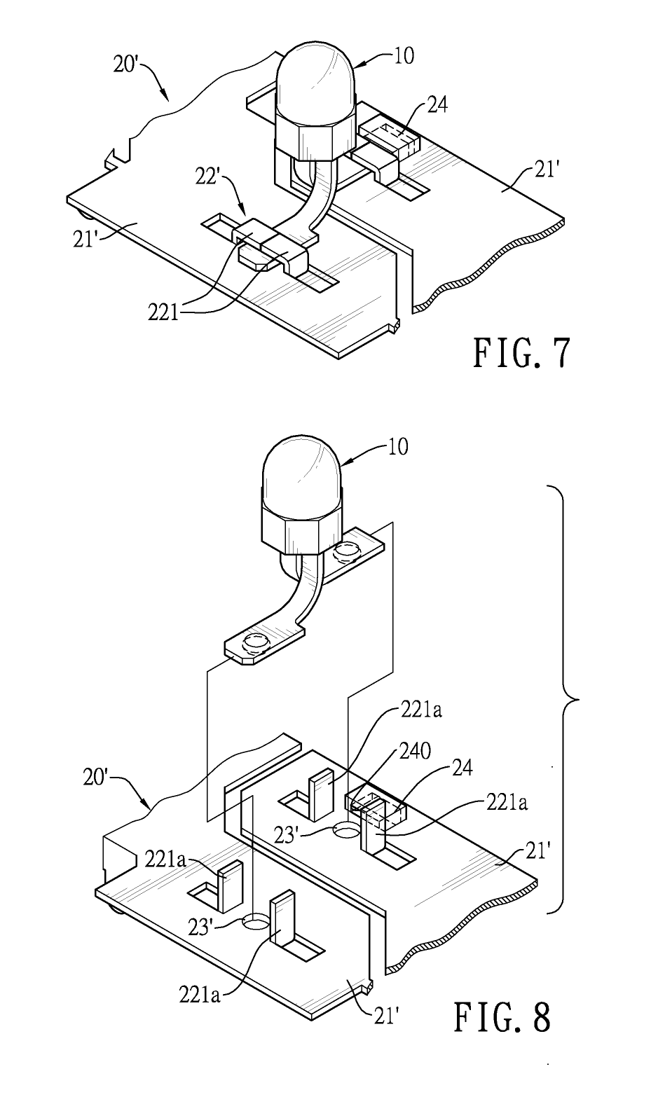

With reference to FIG. 7, in the second embodiment, the light emitting diode 10 has a structure the same as that of the first embodiment except the conductor 20′.

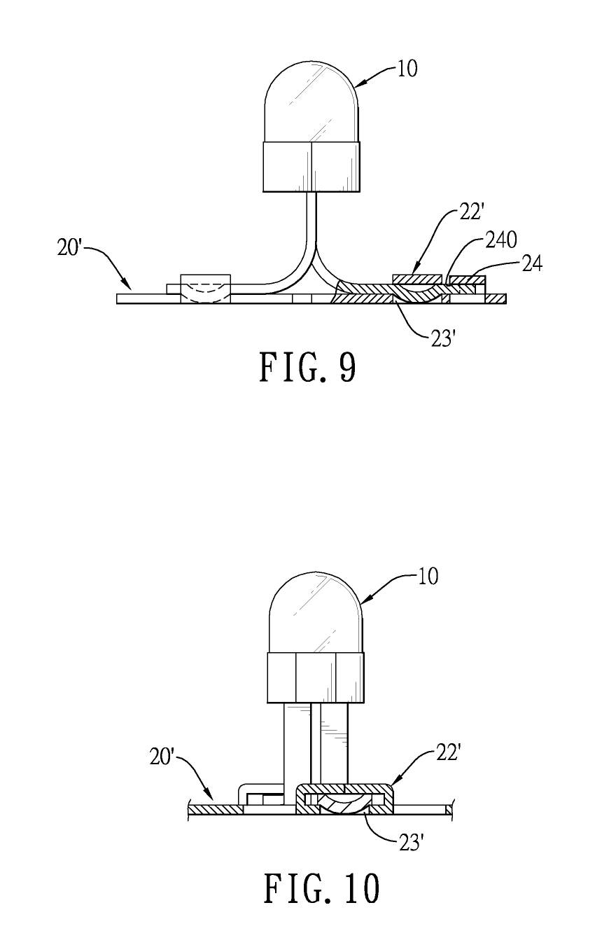

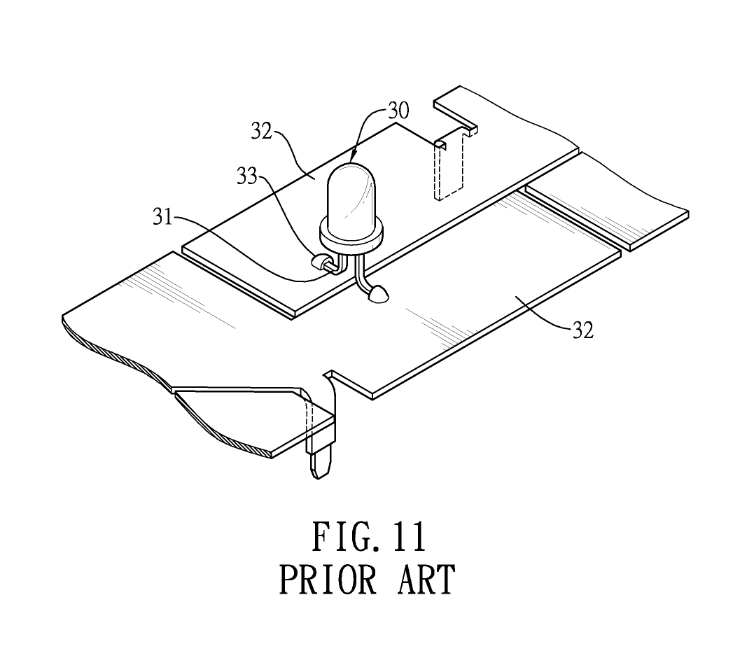

In the present embodiment, each mounting leadframe 22′ of the electrode boards 21′ on the conductor 20′ comprises two bent sheets 221 disposed on the two sides of a corresponding electrode lead 11 of the light emitting diode 10 in order to clamp the corresponding electrode lead 11 between the two bent sheets 221. The bent sheets 221 are formed on the conductor 20′ with a punching process. With reference to FIG. 8, two straight sheets 221a are firstly formed on each electrode board 21′ of the conductor 20′. After mounting each electrode lead 11 of the light emitting diode 10 between the corresponding two straight sheets 221a, the straight sheets 221a are bent face to face to clamp the electrode leads 11 between the bent sheets 221. Additionally, with reference to FIGS. 9 and 10, in the second embodiment, the conductor 20′ further comprises a positioning socket 24. The positioning socket 24 has a socket hole 240 defined in the positioning socket 24 and facing the distal end of one of the electrode leads 11 of the light emitting diode 10 to make the distal end of the corresponding electrode lead inserted into the socket hole 240 of the positioning socket 24. With reference to FIG. 8, after each electrode lead 11 of the light emitting diode 10 is mounted between the corresponding two straight sheets 221a and before the straight sheets are bent, one of the two electrode leads 11 is inserted into the socket hole 240 of the positioning socket 24 to prevent the light emitting diode 10 from toppling down and to facilitate the following process of bending the straight sheets 221a.

In conclusion, with the engagement between the protrusions 12 of the two electrode leads 11 and the two mounting holes 23 in the conductor 20 that are previously formed in the conductor 20, the light emitting diode 10 can be precisely located on the conductor 20 to prevent the light emitting diode 10 from shifting. In addition, the mounting leadframes 22,22′ can hold the electrode leads 11 of the light emitting diode 10 in position because the mounting leadframes 22,22′ are either formed by punching process as in the first embodiment or composed of two bent sheets 221 as in the second embodiment. Accordingly, the light emitting diode 10 can be stably mounted on the conductor 20,20′ and the method for assembling the light emitting diode 10 onto the conductor 20,20′ is more timesaving and convenient.

Even though numerous characteristics and advantages of the present invention have been set forth in the foregoing description, together with details of the structure and features of the invention, the disclosure is illustrative only. Changes may be made in the details, especially in matters of shape, size, and arrangement of parts within the principles of the invention to the full extent indicated by the broad general meaning of the terms in which the appended claims are expressed.

What is claimed is:

1. A mounting device for a light emitting diode (LED) comprising:
a light emitting diode having two electrode leads outwardly bent from each other, and each electrode lead having
a distal end having a bottom surface; and
a protrusion formed on the bottom surface of the distal end;
a conductor having two electrode boards connected respectively with the electrode leads of the light emitting diode, and each electrode board having
a mounting leadframe formed on and protruding from the electrode board and clamping the distal end of one of the electrode leads of the light emitting diode; and
a mounting hole formed in the electrode board and engaging the protrusion on a corresponding one of the electrode leads of the light emitting diode, wherein the distal end of each electrode lead is inserted correspondingly into one of the mounting leadframes.

2. The mounting device according to claim 1,wherein each mounting leadframe is located over a corresponding mounting hole.

3. The mounting device according to claim 1,wherein each mounting leadframe comprises two bent sheets disposed on two sides of the distal end of a corresponding electrode lead of the light emitting diode to clamp the corresponding electrode lead between the two bent sheets.

4. The mounting device according to claim 3,wherein the conductor further comprises a positioning socket having a socket hole defined in the positioning socket and facing the distal end of one of the electrode leads of the light emitting diode to allow the distal end of the corresponding electrode lead of the light emitting diode to be inserted into the socket hole of the positioning socket.

5. The mounting device according to claim 1, wherein each protrusion is hemispherical and each mounting hole is a round hole.

6. The mounting device according to claim 2, wherein each protrusion is hemispherical and each mounting hole is a round hole.

7. The mounting device according to claim 3, wherein each protrusion is hemispherical and each mounting hole is a round hole.

8. The mounting device according to claim 4, wherein each protrusion is hemispherical and each mounting hole is a round hole.

9. The mounting device according to claim 1, wherein the lengths of the mounting leadframes match the widths of the plate-shaped distal ends of the electrode leads.

10. The mounting device according to claim 2, wherein the lengths of the mounting leadframes match the widths of the plate-shaped distal ends of the electrode leads.

11. The mounting device according to claim 3, wherein the lengths of the mounting leadframes match the widths of the plate-shaped distal ends of the electrode leads.

12. The mounting device according to claim 4, wherein the lengths of the mounting leadframes match the widths of the plate-shaped distal ends of the electrode leads.

13. The mounting device according to claim 5, wherein the lengths of the mounting leadframes match the widths of the plate-shaped distal ends of the electrode leads.

14. The mounting device according to claim 6, wherein the lengths of the mounting leadframes match the widths of the plate-shaped distal ends of the electrode leads.

15. The mounting device according to claim 7, wherein the lengths of the mounting leadframes match the widths of the plate-shaped distal ends of the electrode leads.

16. The mounting device according to claim 8, wherein the lengths of the mounting leadframes match the widths of the plate-shaped distal ends of the electrode leads.

17. The mounting device according to claim 1,wherein a recess is formed in the top surface of the distal end of each electrode lead at a position corresponding to the protrusion.

18. The mounting device according to claim 2, wherein a recess is formed in the top surface of the distal end of each electrode lead at a position corresponding to the protrusion.

19. The mounting device according to claim 3, wherein a recess is formed in the top surface of the distal end of each electrode lead at a position corresponding to the protrusion.

20. The mounting device according to claim 4, wherein a recess is formed in the top surface of the distal end of each electrode lead at a position corresponding to the protrusion.
